(19) United States
(12) Patent Application Publication
(10) Pub. No.: US 2008/0298084 A1
(43) Pub. Date: Dec. 4, 2008

(54) LIGHTING SYSTEM FOR THIN REFLECTIVE DISPLAY DEVICES

(75) Inventors: Sen Yang, Palantine, IL (US); Chien-Hui Wen, Vernon Hills, IL (US); Steve C. Emmert, Crystal Lake, IL (US); Yi-Lin Pei, Beijing (CN); James P. Elfering, Antioch, IL (US); Mark J. Carlson, Round Lake, IL (US)

Correspondence Address: PRASS LLP, 2661 Riva Road, Bldg. 1000, Suite 1044, ANNAPOLIS, MD, 21401, US

(73) Assignee: Motorola, Inc., Schaumburg, IL (US)

(21) Appl. No.: 11/755,421

(22) Filed: May 30, 2007

(51) Int. Cl. F21V 13/04; F21V 5/00; H05K 5/02

(52) U.S. Cl. 362/607; 361/681; 362/458

(57) ABSTRACT

A display for a mobile communication device is disclosed. The display may include a first layer with refractive index n₁, having at least a rough surface on one side, a second layer, having refractive index n₂, applied contiguously on a side opposite from the rough side of the first layer, wherein n₁>n₂>nₐᵢᵣ and nₐᵢᵣ, is the refractive index in air media, a reflective display disposed on a side of the second layer opposite from the first layer, and at least one light source located adjacent to at least one edge or side of the first layer.

### BACKGROUND OF THE DISCLOSURE

1. Field of the Disclosure

The disclosure relates to displays for mobile communication devices.

2. Introduction

As mobile communication devices become smaller and thinner, the displays on those devices must become thinner. The battery size is also limited by the compact design. Therefore, there is a demand for using thin, light-weighted and power saving displays for mobile devices.

Some conventional devices, for example, use a thin, highly reflective electro-phoretic display (EPD) that meets these requirements. However, using reflective display may be at the expense of proper illumination of the display. For example, most of the reflective displays are opaque, and cannot use a backlighting system. A front light can light up a reflective display, but the lighting system of a traditional front light is usually thick and needs an air gap between light guide and the display. An expensive anti-reflective coating is usually required to maintain the contrast. A front light guide must be transparent and free of visual artifacts. Non-transparent or scattering light guide material will decrease the amount of light ultimately reaching the center of the display, and result in a low contrast ratio.

### SUMMARY OF THE DISCLOSURE

A display for a mobile communication device is disclosed. The display may include a first layer with refractive index n₁, having at least a rough surface on one side, a second layer, having refractive index n₂, applied contiguously on a side opposite from the rough side of the first layer, wherein n₁>n₂>nₐᵢᵣ and nₐᵢᵣ is the refractive index in air media, a reflective display disposed on a side of the second layer opposite from the first layer, and at least one light source located adjacent to at least one edge or side of the first layer.

### BRIEF DESCRIPTION OF THE DRAWINGS

In order to describe the manner in which the above-recited and other advantages and features of the disclosure can be obtained, a more particular description of the disclosure briefly described above will be rendered by reference to specific embodiments thereof which are illustrated in the appended drawings. Understanding that these drawings depict only typical embodiments of the disclosure and are not therefore to be considered to be limiting of its scope, the disclosure will be described and explained with additional specificity and detail through the use of the accompanying drawings in which:

FIG. 1 is an exemplary diagram of a mobile communication device in accordance with a possible embodiment of the disclosure;

FIG. 2 is a diagram of the layers of an exemplary display in accordance with a possible embodiment of the disclosure;

FIG. 3 illustrates an exemplary display in accordance with a possible embodiment of the disclosure; and

FIG. 4 is an exemplary flowchart illustrating one possible process of fabricating a display in accordance with one possible embodiment of the disclosure.

### DETAILED DESCRIPTION OF THE DISCLOSURE

Additional features and advantages of the disclosure will be set forth in the description which follows, and in part will be obvious from the description, or may be learned by practice of the disclosure. The features and advantages of the disclosure may be realized and obtained by means of the instruments and combinations particularly pointed out in the appended claims. These and other features of the present disclosure will become more fully apparent from the following description and appended claims, or may be learned by the practice of the disclosure as set forth herein.

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

The disclosure comprises a variety of embodiments, such as a method and apparatus and other embodiments that relate to the basic concepts of the disclosure.

The following terms have the definitions as stated below:
a. A “layer” herein may be solid or liquid state
b. The “refractive index” of a medium herein may be defined as the ratio of the phase velocity of a wave phenomenon in a reference medium to the velocity in the medium of itself.
c. “nₐᵢᵣ” herein may be the refractive index in air media at reference temperature.

This disclosure concerns a display for a mobile communication device that may include a very thin layer with a very high refractive index to serve as the front light which may be laminated or coated onto a reflective type of display. Also, the display may include a rough surface on top of the high refractive index layer that can bend the light towards the reflective display.

However, between the thin layer and the reflective display may be a very thin layer with low refractive index. This layer of low refractive index may be an adhesive to laminate the thin very high refractive index layer to the reflective display. The low index layer may also be coated onto one side of the high refractive index layer. In any event, the low index adhesive, coating or film work with the high index layer so that light can be guided to the center of the display through total internal reflection.

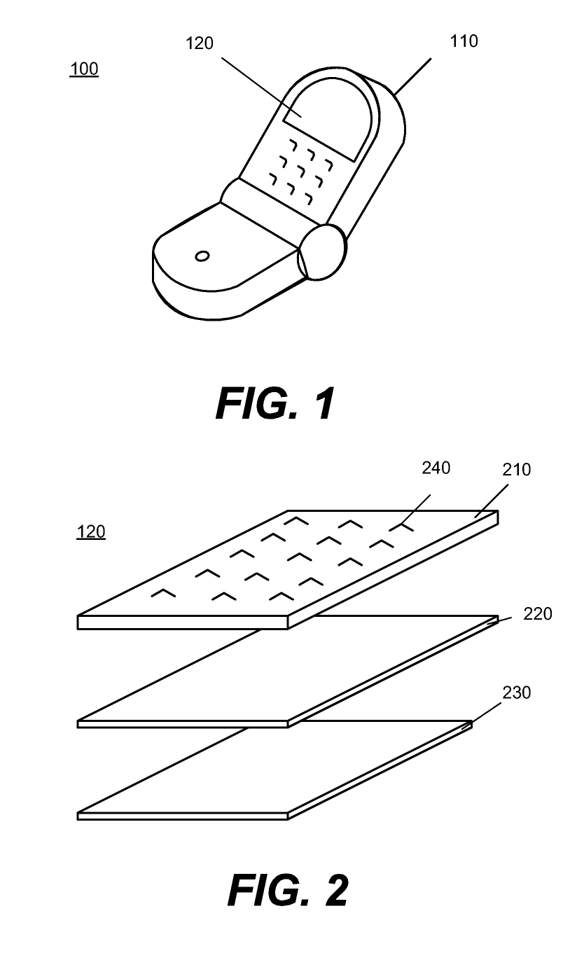

FIG. 1 illustrates an exemplary mobile communication device 100 in accordance with a possible embodiment of the disclosure. In particular, the mobile communication device 100 may include a casing 110 and a display 120.

The mobile communication device 100 may be a portable MP3 player, satellite radio receiver, AM/FM radio receiver, satellite television, portable music player, portable laptop, portable computer, e-book, wireless radio, wireless telephone, portable digital video recorder, cellular telephone, mobile telephone, or personal digital assistant PDA), combinations of the above, for example.

The casing 110 may be made at any durable material synthetic or metal capable of housing components of the mobile communication device 100. The display 120 will be described below with respect to FIGS. 2-4.

FIG. 2 is a diagram of the layers of an exemplary display 120 in accordance with a possible embodiment of the disclosure. The display 120 may include a high refractive index layer 210, a low refractive index layer 220, and a reflective display 230. The high index refractive layer 210 may be made of any material that has a refractive index n₁, where 1.5<n₁≦1.9 or 1.6≦n₁≦1.85, for example. The high refractive index layer 210 may include a rough surface 240 which may include bumps, mounds, small prisms, etc. capable of bending light toward the reflective display 230. The high refractive index layer 210 is very thin such that it may have a thickness of 0.10 to 0.25 mm, for example.

The low refractive index layer 220 has a refractive index n₂, where 1.2≦n₂≦1.5 or 1.2≦n₃≦1.5, for example. Note that low refractive index layer 220 may be a low index coating applied directly onto high refractive index layer 210 or an adhesive. There could also be an adhesive layer between the low refractive index layer 220 and the reflective display 230 with any index of refraction.

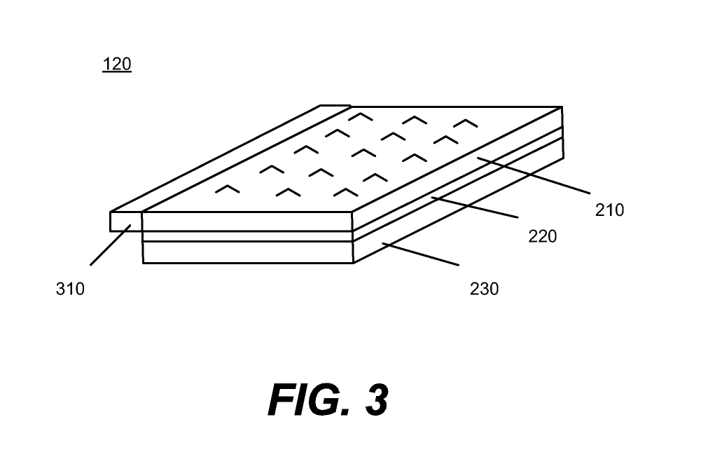

FIG. 3 illustrates the exemplary display 120 from FIG. 2 shown in layers in accordance with a possible embodiment of the disclosure. The exemplary display 120 may include high refractive index layer 210, low refractive index layer 220, and reflective display 230 as shown in FIG. 2. FIG.3 also includes light source 310. Light source 310 may include one or more light guides or light sources positioned adjacent to the refractive index layer 210, for example.

Once light is directed into the display 120 structure by the light source 310, high refractive index layer and the low refractive index layer work together so that light can be guided to the center of the display through total internal reflection. By combining these layers having different refractive properties, less light is dissipated and more light is present to more fully illuminate the display. Accordingly, less power may be required in order to obtain a brighter display illumination.

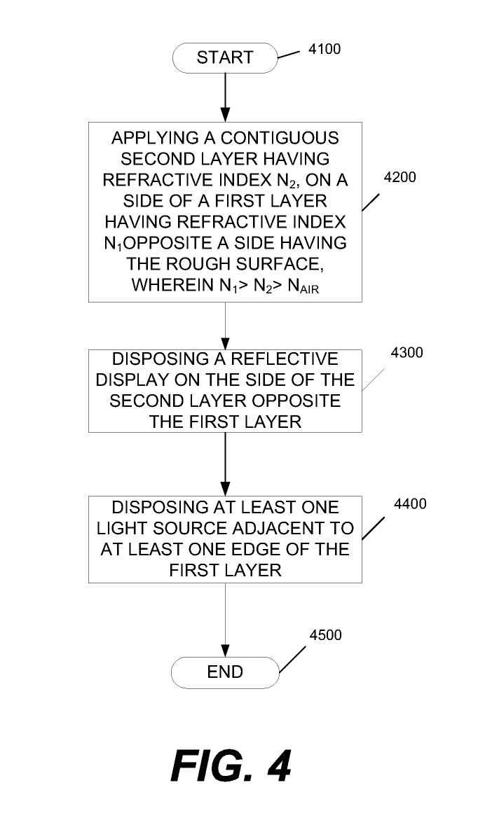

FIG. 4 is an exemplary flowchart illustrating some of the basic steps associated with a display fabrication process in accordance with a possible embodiment of the disclosure. The process begins at step 4100 and continues to step 4200 where the process applies a contiguous low refractive index layer 220 (second layer) on a side of the high refractive index layer 210 (first layer) opposite a side having the rough surface 240. The rough surface 240 may be pre-formed on the high refractive index layer 210 or it may be made or fabricated as part of the process.

At step 4300, the process disposes a reflective display 230 on the side of the low refractive index layer 220 opposite the high refractive index layer 210. At step 4400, the process disposes at least one light source 310 adjacent to at least one edge of the high refractive index layer 210. The process goes to step 4400 and ends.

Although the above description may contain specific details, they should not be construed as limiting the claims in any way. Other configurations of the described embodiments of the disclosure are part of the scope of this disclosure. For example, the principles of the disclosure may be applied to each individual user where each user may individually deploy such a system. This enables each user to utilize the benefits of the disclosure even if any one of the large number of possible applications do not need the functionality described herein. It does not necessarily need to be one system used by all end users. Accordingly, the appended claims and their legal equivalents should only define the disclosure, rather than any specific examples given.

We claim:

1. A display for a mobile communication device, comprising:
a first layer with refractive index n₁, having at least a rough surface on one side;
a second layer, having refractive index n₂, applied contiguously on a side opposite from the rough side of the first layer, wherein n₁>n₂>nₐᵢᵣ and nₐᵢᵣ is the refractive index in air media;
a reflective display disposed on a side of the second layer opposite from the first layer; and
at least one light source located adjacent to at least one edge or side of the first layer.

2. The display of claim 1, wherein the second layer is one of an optically clear adhesive and a transparent film.

3. The display of claim 1, wherein the second layer is coated directly onto the first layer.

4. The display of claim 1, wherein the at least one light source is a light guide extending the entire length of at least one edge of the first layer.

5. The display of claim 1, wherein 1.5<n₁≦1.9, and 1.2≦n₂≦1.5.

6. The display of claim 1, wherein 1.6≦n₁≦1.85, and 1.3≦n₂≦1.5.

7. The display of claim 1, wherein a thickness of the first layer is between 0.10 to 0.5 millimeters.

8. A mobile communication device, comprising:
a casing for housing components of the mobile communication device; and
a display housed inside the casing, comprising:
a first layer with refractive index n₁, having at least a rough surface on one side;
a second layer, having refractive index n₂, applied contiguously on a side opposite from the rough side of the first layer, wherein n₁>n₂>nₐᵢᵣ is the refractive index in air media;
a reflective display disposed on a side of the second layer opposite from the first layer; and
at least one light source located adjacent to at least one edge of the first layer.

9. The mobile communication device of claim 8, wherein the second layer is one of an optically clear adhesive and a transparent film.

10. The mobile communication device of claim 8, wherein the second layer is coated directly onto the first layer.

11. The mobile communication device of claim 8, wherein 1.5<n₁≦1.9, and 1.2≦n₂≦1.5.

12. The mobile communication device of claim 8, wherein 1.6≦n₁≦1.85, and 1.3≦n₂≦1.5.

13. The mobile communication device of claim 8, wherein a thickness of the first layer is between 0.10 to 0.5 millimeters.

14. The mobile communication device of claim 8, wherein at least one light source is a light guide extending the entire length of at least one edge of the first layer.

15. The mobile communication device of claim 8, wherein the mobile communication device may be one of a portable MP3 player, satellite radio receiver, AM/FM radio receiver, satellite television, portable music player, e-book, portable laptop, portable computer, wireless radio, wireless telephone, portable digital video recorder, cellular telephone, mobile telephone, and personal digital assistant.

16. A method of fabricating a display for a mobile communication device, comprising:
applying a contiguous second layer having refractive index n₂, on a side of a first layer having refractive index n₁ opposite a side having the rough surface, wherein n₁>n₂>and nₐᵢᵣ is the refractive index in air media;
disposing a reflective display on a side of the second layer opposite the first layer; and
disposing at least one light source at adjacent to at least one edge of the first layer.

17. The method of claim 16, wherein the second layer is one of an optically clear adhesive and a transparent film.

18. The method of claim 16, wherein the second layer is applied directly onto the first layer.

19. The method of claim 16, wherein 1.5<n₁≦1.9, and 1.2≦n₂≦1.5.

20. The method of claim 16, wherein 1.6≦n₁≦1.85, and 1.3≦n₂≦1.5.
